(19) United States
(12) Patent Application Publication
(10) Pub. No.: US 2023/0139725 A1
(43) Pub. Date: May 4, 2023

(54) POWER MODULE

(71) Applicant: Lite-On Singapore Pte Ltd, Singapore (SG)

(72) Inventors: Yijun Pan, Singapore (SG); Yingqian Zhang, Singapore (SG); Rayyan Bin Fairuz, Singapore (SG)

(73) Assignee: Lite-On Singapore Pte Ltd, Singapore (SG)

(21) Appl. No.: 17/722,407

(22) Filed: Apr. 18, 2022

(30) Foreign Application Priority Data
Nov. 4, 2021 (CN) 202111300339.X

(51) Int. Cl. H05K 7/20

(52) U.S. Cl. CPC H05K 7/209; H05K 7/20436; H05K 7/20409

(57) ABSTRACT

A power module includes a first shell, a second shell, a circuit board assembly, and a heat dissipation encapsulation. The second shell is closed relative to the first shell and forms an accommodating space together with the first shell. The circuit board assembly is disposed in the accommodating space, and includes a circuit board body, a plurality of power components disposed on the circuit board body, and a plurality of electrical connectors electrically connected to the circuit board body. The electrical connectors are exposed from the first shell. The heat dissipation encapsulation is filled in the accommodating space and covers the circuit board assembly.

### CROSS-REFERENCE TO RELATED APPLICATION

This application claims the priority benefit of Chinese application no. 202111300339.X, filed on Nov. 4, 2021. The entirety of the above-mentioned patent application is hereby incorporated by reference herein and made a part of this specification.

### BACKGROUND

### Technical Field

The disclosure relates to a power module. Particularly, the disclosure relates to a power module with good heat dissipation efficiency.

### Description of Related Art

Currently, in application to electric vehicles, data centers, artificial intelligence, machine learning, etc., it is required that a power module can achieve high-performance power transmission, and has an internal structure of compact arrangement so as to increase power density. Such a power module generates high heat during operation. Currently, a plurality of heat dissipation fins are disposed in combination with fans to improve the heat dissipation performance of the power module. However, since heat dissipation fins and fans are relatively space-occupying, it may be difficult for the power module to meet the requirements of compact arrangement.

### SUMMARY

The disclosure provides a power module that achieves good heat dissipation.

In the disclosure, a power module includes a first shell, a second shell, a circuit board assembly, and a heat dissipation encapsulation. The second shell is closed relative to the first shell and forms an accommodating space together with the first shell. The circuit board assembly is disposed in the accommodating space, and includes a circuit board body, a plurality of power components disposed on the circuit board body, and a plurality of electrical connectors electrically connected to the circuit board body. The electrical connectors are exposed from the first shell. The heat dissipation encapsulation is filled in the accommodating space and covers the circuit board assembly.

In an embodiment of the disclosure, the circuit board body includes a first surface and a second surface opposite to each other. A part of the power components is disposed on the first surface of the circuit board body, and another part of the power components is disposed on the second surface of the circuit board body.

In an embodiment of the disclosure, the circuit board body is an insulated metal substrate. The circuit board body includes a heat dissipation layer, an insulating layer, and a circuit layer stacked in sequence. The power components are disposed on the circuit layer.

In an embodiment of the disclosure, the heat dissipation layer is thermally coupled to the second shell.

In an embodiment of the disclosure, a thickness of the heat dissipation layer is greater than a thickness of the insulating layer, and the thickness of the heat dissipation layer is greater than a thickness of the circuit layer.

In an embodiment of the disclosure, the electrical connectors include a plurality of electrically conductive pillars. The circuit board body includes a first surface. At least a part of the power components is disposed on the first surface. The first shell includes a plurality of holes. The electrically conductive pillars protrude from the first surface, pass through the holes, and protrude from the first shell.

In an embodiment of the disclosure, the electrical connectors include a plurality of electrically conductive bars connected to side edges of the circuit board body. The first shell includes a plurality of sidewalls and a plurality of through slots located on the sidewalls. The electrically conductive bars are located in the through slots and spaced apart from the first shell.

In an embodiment of the disclosure, each of the electrically conductive bars is in a shape of a U-shaped bar.

In an embodiment of the disclosure, the electrically conductive bars are flush with or below a surface of the first shell away from the second shell.

In an embodiment of the disclosure, the electrical connectors are located around the power components.

In an embodiment of the disclosure, the power components include an inductor, a transistor, a coil transformer, or a planar transformer.

In an embodiment of the disclosure, a thermal conductivity coefficient of the second shell is greater than or equal to a thermal conductivity coefficient of the first shell, and the heat dissipation encapsulation is thermally coupled to the second shell.

In an embodiment of the disclosure, a material of the first shell includes metal or a ceramic material.

In an embodiment of the disclosure, a material of the second shell includes aluminum or copper.

In an embodiment of the disclosure, the first shell is a box, and the second shell is a thermally conductive plate.

In an embodiment of the disclosure, the first shell is a plate, and the second shell is a thermally conductive box.

In an embodiment of the disclosure, a thermal conductivity coefficient of the second shell is greater than or equal to a thermal conductivity coefficient of the first shell, and a surface area of the second shell is greater than a surface area of the first shell.

In an embodiment of the disclosure, the power module does not include a heat dissipation fin.

In an embodiment of the disclosure, the heat dissipation encapsulation is in direct contact with the first shell and the second shell.

In an embodiment of the disclosure, the heat dissipation encapsulation is in direct contact with the power components.

Based on the foregoing, the second shell of the power module according to the embodiments of the disclosure is closed relative to the first shell and forms the accommodating space together with the first shell. The circuit board assembly is disposed in the accommodating space and includes the power components. The heat dissipation encapsulation is filled in the accommodating space and covers the circuit board assembly. In the power module of the disclosure, with the above design, the heat dissipation encapsulation filled in the accommodating space can effectively transfer the high heat generated by the circuit board assembly to the shells to improve the heat dissipation efficiency. Compared with the conventional structure, which needs to lower the temperature using heat dissipation fins that occupy a larger space, the power module of the disclosure has a smaller volume and a more compact component arrangement, thereby achieving high power density.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of appearance of a power module according to an embodiment of the disclosure.

FIG. 2 is a perspective view of the power module of FIG. 1.

FIG. 3 is a schematic view of a first shell of the power module of FIG. 1 being moved up.

FIG. 4 is a schematic side view of the circuit board assembly of the power module of FIG. 1.

FIG. 5 is a schematic side view of a circuit board assembly of a power module according to another embodiment of the disclosure.

FIG. 6 is a schematic view of a power module according to another embodiment of the disclosure.

FIG. 7 is a schematic view of a power module according to another embodiment of the disclosure.

FIG. 8 is a schematic view of a power module according to another embodiment of the disclosure.

FIG. 9 is a perspective view of the power module of FIG. 8.

FIG. 10 is a schematic perspective view of a power module according to another embodiment of the disclosure.

FIG. 11 is a schematic view of a first shell of the power module of FIG. 10 being moved up.

FIG. 12 is a schematic side view of a circuit board assembly of the power module of FIG. 10.

FIG. 13 is a schematic side view of a circuit board assembly of a power module according to another embodiment of the disclosure.

FIG. 14 is a schematic view of a power module according to another embodiment of the disclosure.

FIG. 15 is a schematic view of a power module according to another embodiment of the disclosure.

### DESCRIPTION OF THE EMBODIMENTS

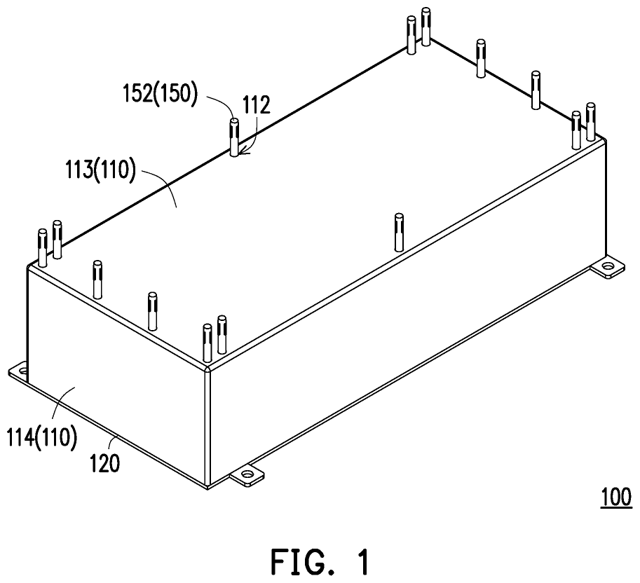

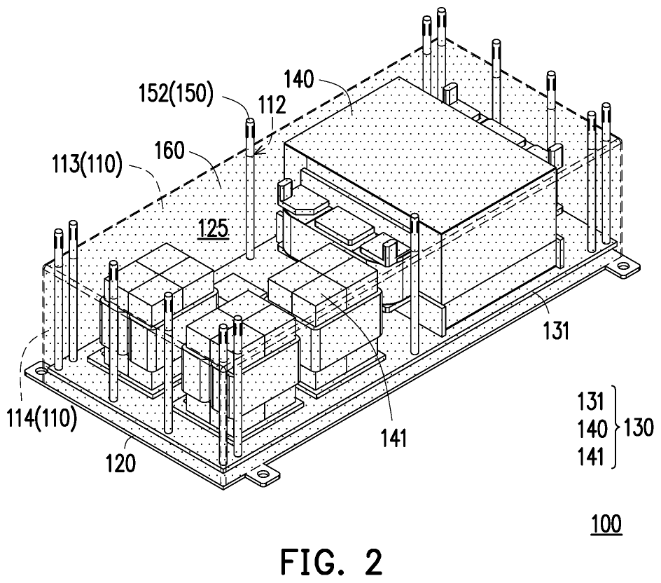

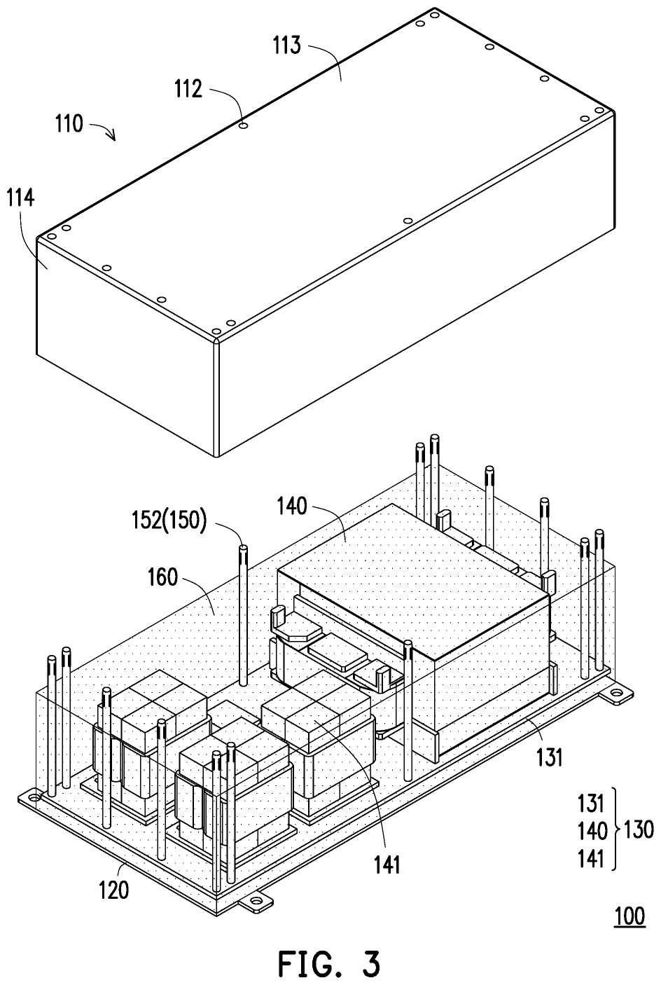

FIG. 1 is a schematic view of appearance of a power module according to an embodiment of the disclosure. FIG. 2 is a perspective view of the power module of FIG. 1. FIG. 3 is a schematic view of a first shell of the power module of FIG. 1 being moved up. With reference to FIG. 1 to FIG. 3, a power module 100 of this embodiment includes a first shell 110, a second shell 120, a circuit board assembly 130 (FIG. 2), and a heat dissipation encapsulation 160 (FIG. 2).

The second shell 120 is closed relative to the first shell 110 and forms an accommodating space 125 (FIG. 2) together with the first shell 110. As shown in FIG. 3, in this embodiment, the first shell 110 is a box, and the second shell 120 is a thermally conductive plate, but the shapes of the first shell 110 and the second shell 120 are not limited thereto. The first shell 110 includes a plurality of sidewalls 114 and a top plate 113. In addition, in this embodiment, a thermal conductivity coefficient of the second shell 120 is greater than or equal to a thermal conductivity coefficient of the first shell 110. A material of the first shell 110 is, for example, metal or a ceramic material. A material of the second shell 120 is, for example, a material with high thermal conductivity, such as aluminum or copper. Nonetheless, the materials of the first shell 110 and the second shell 120 are not limited thereto.

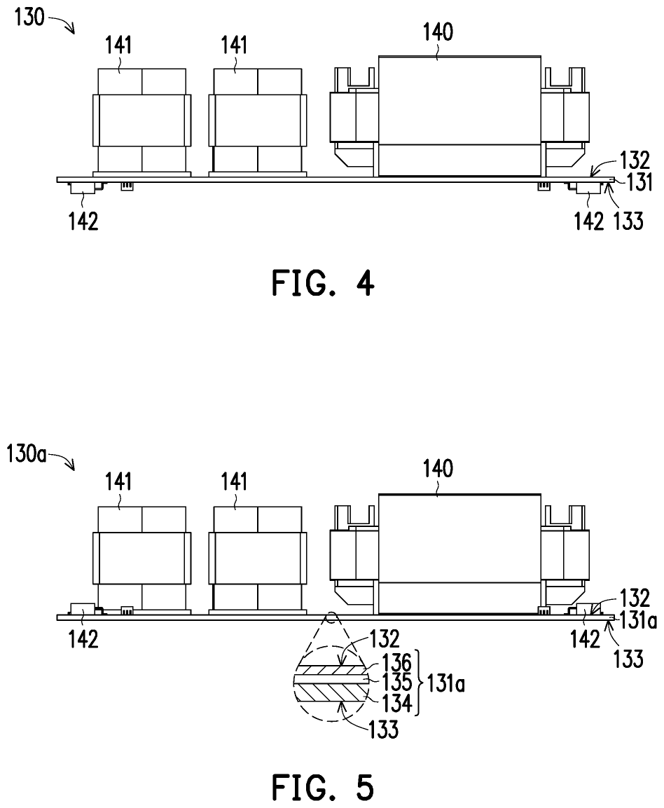

As shown in FIG. 2, the circuit board assembly 130 is disposed in the accommodating space 125. The circuit board assembly 130 includes a circuit board body 131, a plurality of power components 140, 141, and 142 disposed on the circuit board body 131, and a plurality of electrical connectors 150 electrically connected to the circuit board body 131. In this embodiment, the power components 140, 141, and 142 include a transformer (e.g., the power component 140), an inductor (e.g., the power component 141), and a transistor (e.g., the power component 142 of FIG. 4). Nonetheless, the types of the power components 140, 141, and 142 are not limited thereto.

FIG. 4 is a schematic side view of the circuit board assembly 130 of the power module 100 of FIG. 1. With reference to FIG. 4, in this embodiment, the circuit board body 131 is a multilayer circuit board. The circuit board body 131 includes a first surface 132 and a second surface 133 opposite to each other. The power components 140 and 141 are disposed on the first surface 132 of the circuit board body 131, and the power component 142 is disposed on the second surface 133 of the circuit board body 131.

With reference back to FIG. 2, the electrical connectors 150 are located around the power components 140 and 141. The electrical connectors 150 are electrically connected to the circuit board body 131 and are exposed from the first shell 110. Specifically, in this embodiment, the electrical connectors 150 include a plurality of electrically conductive pillars 152. The first shell 110 includes a plurality of holes 112. The electrically conductive pillars 152 protrude from the first surface 132 of the circuit board body 131, pass through the holes 112 of the first shell 110, and protrude from the first shell 110. Therefore, the circuit board assembly 130 of the power module 100 may be connected to an external motherboard (not shown) through the portion of the electrically conductive pillars 152 protruding from the first shell 110.

In addition, the heat dissipation encapsulation 160 is filled in the accommodating space 125 and covers the circuit board assembly 130. In this embodiment, the heat dissipation encapsulation 160 covers the power components 140, 141, and 142, and is filled in the space between the circuit board body 131 and the first shell 110 and the space between the circuit board body 131 and the second shell 120. In other words, the heat dissipation encapsulation 160 is thermally coupled to the circuit board assembly 130, the first shell 110, and the second shell 120. In this embodiment, the heat dissipation encapsulation 160 is in direct contact with the first shell 110, the second shell 120, and the power components 140, 141, and 142.

Therefore, during operation of the power module 100, the high heat generated by the power components 140, 141, and 142 may be conducted to the first shell 110 and the second shell 120 through the heat dissipation encapsulation 160 to improve the heat dissipation efficiency. The power module 100 may subsequently be connected to a water cooler (not shown), so that the heat energy conducted to the first shell 110 and the second shell 120 can be taken away by the water cooler to lower the temperature of the power module 100.

In an embodiment, since the power module 100 is connected to the motherboard through the electrical connectors 150 protruding from the first shell 110, the water cooler may be disposed on a surface of the second shell 120 away from the first shell 110, but the position of the water cooler is not limited thereto.

It is worth mentioning that, as shown in FIG. 2, in this embodiment, the power module 100 does not include heat dissipation fin disposed therein. Compared with the conventional structure, which needs to lower the temperature using heat dissipation fins that occupy a larger space, the power module 100 of this embodiment has a smaller volume and a more compact component arrangement. Therefore, the power density of the power module 100 of this embodiment can be significantly improved.

In an embodiment, the dimensions of length, width, and height of the power module 100 may be 200 millimeters (mm), 100 mm, and 57 mm. In another embodiment, the dimensions of length, width, and height of the power module 100 may be 120 mm, 60 mm, and 35 mm. Under such small sizes, the power module 100 achieves high current transmission, which may reach up to 1,000 amperes, and has good performance.

FIG. 5 is a schematic side view of a circuit board assembly of a power module according to another embodiment of the disclosure. With reference to FIG. 5, the main difference between a circuit board assembly 130a of FIG. 5 and the circuit board assembly 130 of FIG. 4 lies in the types of a circuit board body 131a and the circuit board body 131. In this embodiment, the circuit board body 131a is an insulated metal substrate (IMS). The circuit board body 131a includes a heat dissipation layer 134, an insulating layer 135, and a circuit layer 136 stacked in sequence. A thickness of the heat dissipation layer 134 is greater than a thickness of the insulating layer 135, and the thickness of the heat dissipation layer 134 is greater than a thickness of the circuit layer 136, which achieves better heat dissipation. Since the bottom of the circuit board body 131a is the heat dissipation layer 134, it achieves better heat dissipation. In addition, in this embodiment, the power components 140, 141, and 142 are each disposed on the circuit layer 136, namely on the first surface 132.

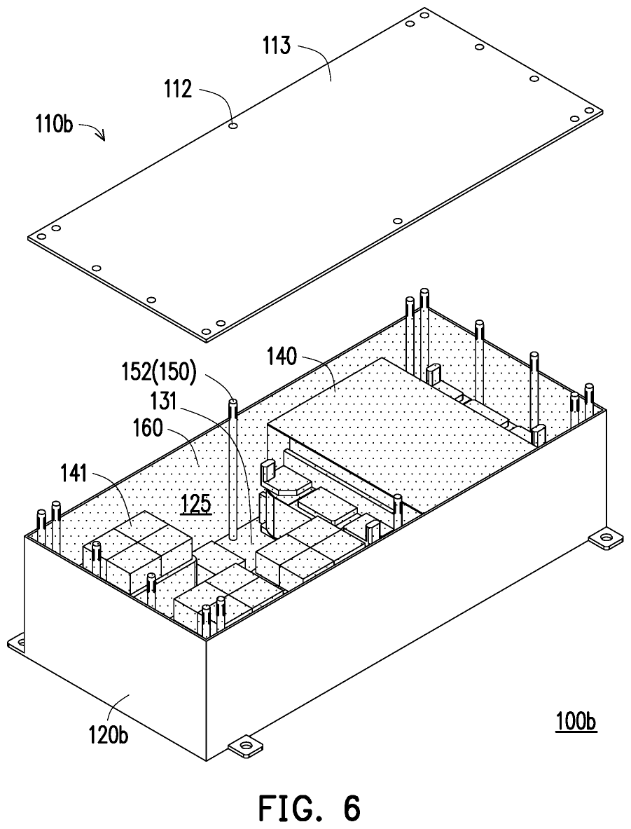

FIG. 6 is a schematic view of a power module according to another embodiment of the disclosure. With reference to FIG. 6, the main difference between a power module 100b of FIG. 6 and the power module 100 of FIG. 2 lies in the shapes of a first shell 110b and the first shell 110 and the shapes of a second shell 120b and the second shell 120. In this embodiment, the first shell 110b is a plate 113, and the second shell 120b is a thermally conductive box. Nonetheless, the shapes of the first shell 110b and the second shell 120b are not limited thereto.

Likewise, in this embodiment, a thermal conductivity coefficient of the second shell 120b is greater than or equal to a thermal conductivity coefficient of the first shell 110b. A material of the first shell 110b is, for example, metal or a ceramic material. A material of the second shell 120b is, for example, a material with high thermal conductivity, such as aluminum or copper. Nonetheless, the materials of the first shell 110b and the second shell 120b are not limited thereto.

Since a size and a surface area of the second shell 120b are greater than a size and a surface area of the first shell 110b, and the thermal conductivity coefficient of the second shell 120b is greater than or equal to the thermal conductivity coefficient of the first shell 110b, the power module 100b of this embodiment achieves better heat dissipation.

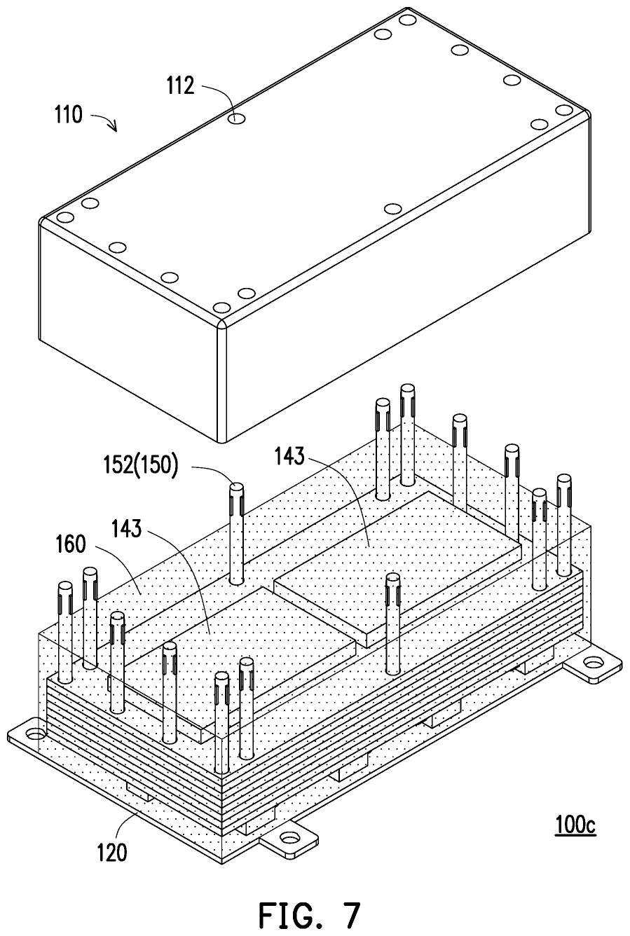

FIG. 7 is a schematic view of a power module according to another embodiment of the disclosure. With reference to FIG. 7, the main difference between a power module 100c of FIG. 7 and the power module 100 of FIG. 2 lies in the types of a power component 143 (FIG. 7) and the power components 140, 141, and 142 (FIG. 2). In this embodiment, the power component 143 includes two planar transformers.

In other words, in the power module 100c, the power component 143 as required may be selected depending on the requirements. Then, the heat energy generated by the power component 143 may be conducted to the first shell 110 and the second shell 120 by utilizing the heat dissipation encapsulation 160. Later, the heat energy may be taken away by a water cooler (not shown) to achieve good heat dissipation and high power density.

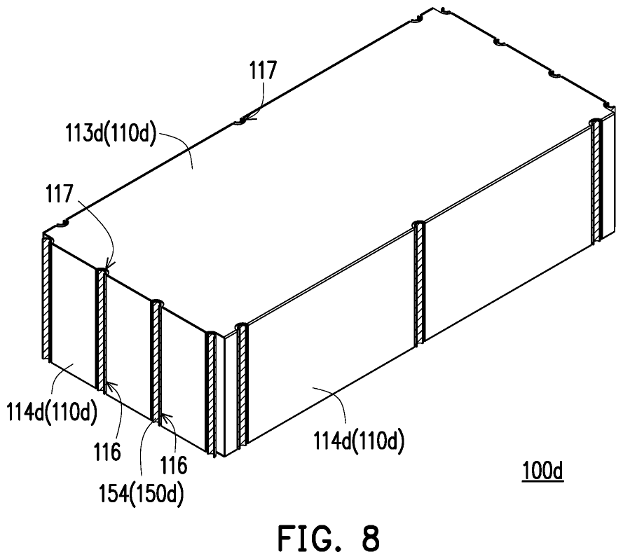

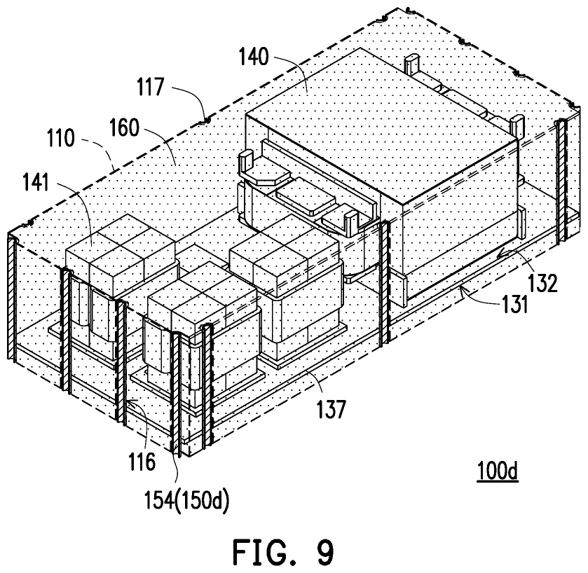

FIG. 8 is a schematic view of a power module according to another embodiment of the disclosure. FIG. 9 is a perspective view of the power module of FIG. 8. With reference to FIG. 8 to FIG. 9, the main difference between a power module 100d of FIG. 9 and the power module 100 of FIG. 2 lies in the types of a plurality of electrical connectors 150d and the electrical connectors 150.

In this embodiment, the electrical connectors 150d include a plurality of electrically conductive bars 154 connected to side edges 137 of the circuit board body 131 to be conductive with the circuit board body 131. Each of the electrical connectors 150d is in a shape of, for example, a U-shaped bar. The electrical connectors 150 are exposed from the first shell 110, and the opening of the U-shape faces outwards.

Specifically, the first shell 110 includes a plurality of sidewalls 114d, a plurality of through slots 116 located on the sidewalls 114d, a plate 113d connected to the sidewalls 114d, and a plurality of recessed holes 117 located on the plate 113d. The positions of the recessed holes 117 correspond to the positions of the through slots 116. In this embodiment, the first shell 110 is, for example, metal. The electrically conductive bars 154 are located in the through slots 116 and the recessed holes 117 and are spaced apart from the first shell 110 to prevent a short circuit. In this embodiment, the electrically conductive bars 154 are flush with or below a surface (i.e., an upper surface) of the first shell 110 away from the second shell 120. In other words, the electrically conductive bars 154 do not extend beyond the upper surface of the first shell 110.

When the power module 100d of this embodiment is mounted on the motherboard, electrically conductive ribs of the motherboard (not shown) may extend into U-shaped recessed grooves of the electrical connectors 150d to be aligned with and conductive with the power module 100d. Specifically, the electrically conductive rib of the motherboard is in a shape of, for example, a cylinder (but not limited thereto). The outer contour of the electrically conductive rib corresponds to the inner contour of the U-shaped recessed groove of the electrical connectors 150d. Therefore, when the power module 100d is mounted on the motherboard, the electrically conductive ribs of the motherboard are inserted into the U-shaped recessed groove of the electrical connectors 150d. In other words, the electrical connectors 150d contacts/encloses a part of the electrically conductive ribs of the motherboard and are conductive.

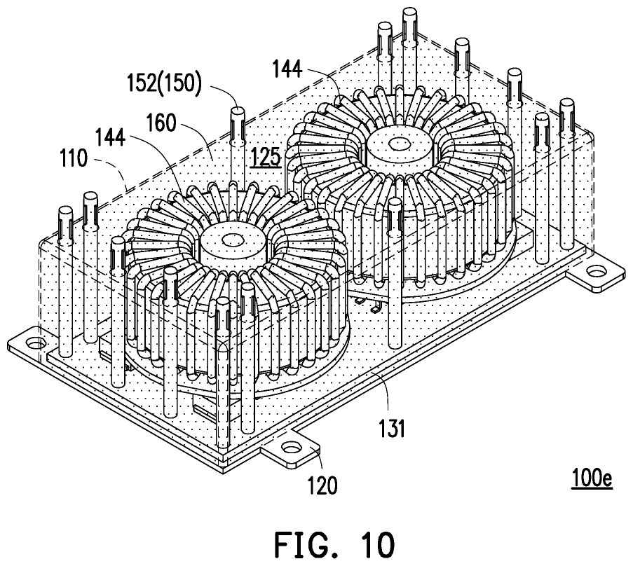

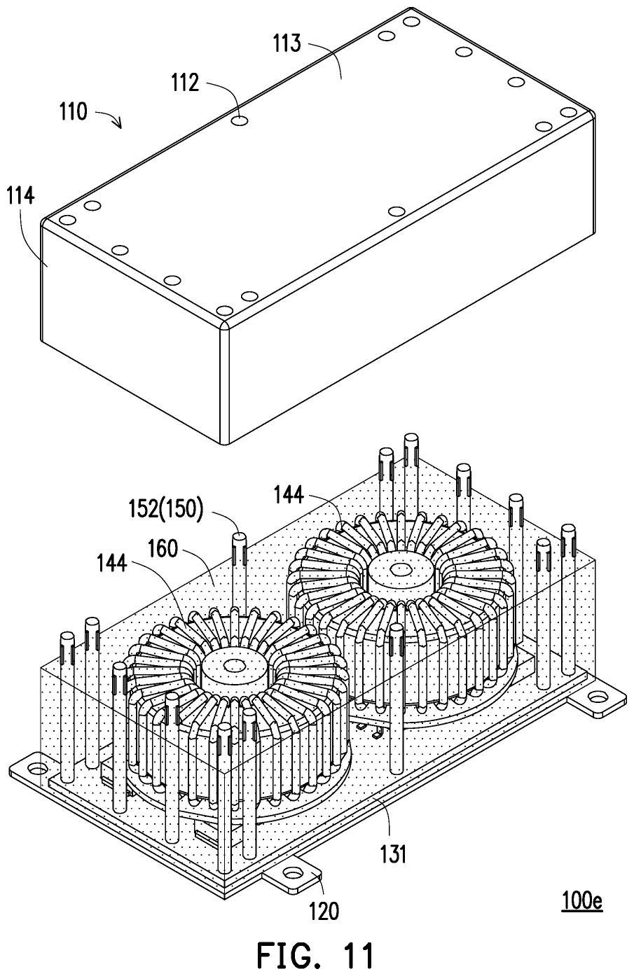

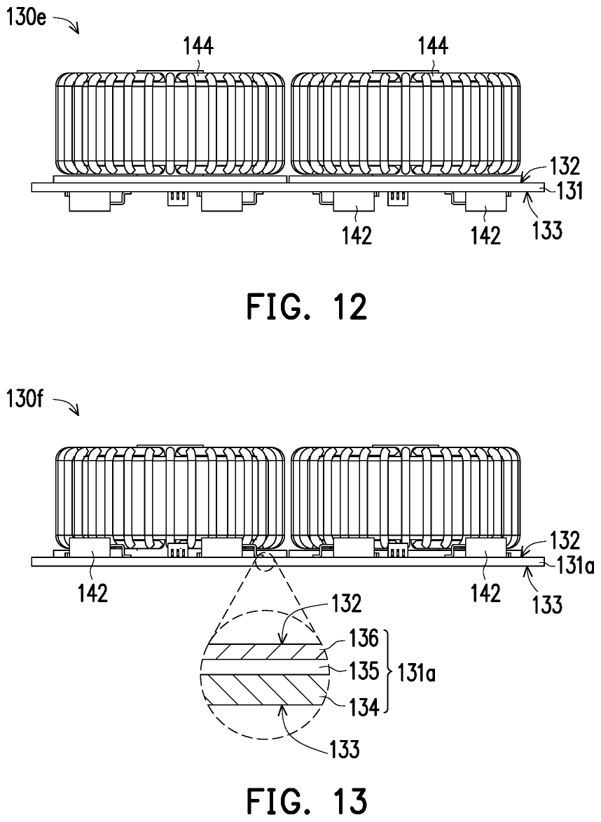

FIG. 10 is a schematic perspective view of a power module according to another embodiment of the disclosure. FIG. 11 is a schematic view of a first shell of the power module of FIG. 10 being moved up. FIG. 12 is a schematic side view of a circuit board assembly of the power module of FIG. 10. With reference to FIG. 10 to FIG. 12, the main difference between a power module 100e of FIG. 10 and the power module 100 of FIG. 2 lies in the types of a power component 144 (FIG. 10) and the power components 140 and 141 (FIG. 2).

In this embodiment, the power component 144 includes a coil transformer. Nonetheless, the types of the power component 144 are not limited thereto. As shown in FIG. 12, the power component 144 (a coil transformer) is disposed on the first surface 132 of the circuit board body 131, and the power component 142 (a transistor) is disposed on the second surface 133 of the circuit board body 131.

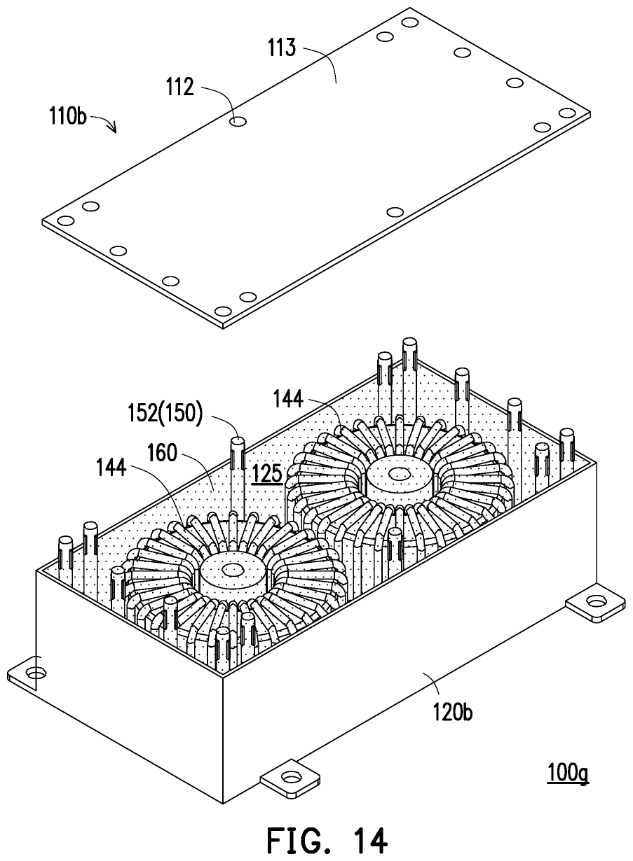

FIG. 13 is a schematic side view of a circuit board assembly of a power module according to another embodiment of the disclosure. With reference to FIG. 13, the main difference between a power module 100f of FIG. 13 and the power module 100e of FIG. 12 lies in the following. In this embodiment, the circuit board body 131a is an insulated metal substrate (IMS). The circuit board body 131a includes the heat dissipation layer 134, the insulating layer 135, and the circuit layer 136 stacked in sequence. The power component 144 (a coil transformer) and the power components 142 (a transistor) are each disposed on the circuit layer 136.

FIG. 14 is a schematic view of a power module according to another embodiment of the disclosure. With reference to FIG. 14, the main difference between a power module 100g of FIG. 14 and the power module 100e of FIG. 11 lies in that, in this embodiment, the first shell 110b is a plate 113, and the second shell 120b is a thermally conductive box. Nonetheless, the shapes of the first shell 110b and the second shell 120b are not limited thereto.

Likewise, in this embodiment, the thermal conductivity coefficient of the second shell 120b is greater than or equal to the thermal conductivity coefficient of the first shell 110b. The material of the first shell 110b is, for example, metal or a ceramic material. The material of the second shell 120b is, for example, a material with high thermal conductivity, such as aluminum or copper. Nonetheless, the materials of the first shell 110b and the second shell 120b are not limited thereto.

Since the size and the surface area of the second shell 120b are greater than the size and the surface area of the first shell 110b, and the thermal conductivity coefficient of the second shell 120b is greater than or equal to the thermal conductivity coefficient of the first shell 110b, the power module 100g of this embodiment achieves better heat dissipation.

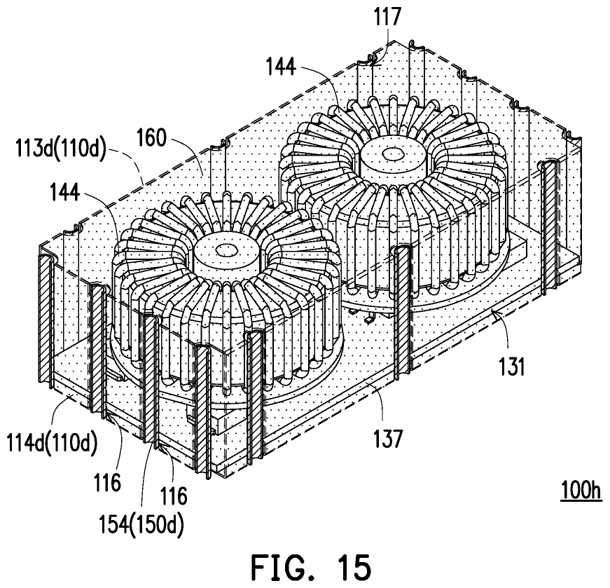

FIG. 15 is a schematic view of a power module according to another embodiment of the disclosure. With reference to FIG. 15, the main difference between a power module 100h of FIG. 15 and the power module 100e of FIG. 11 lies in the types of the electrical connectors 150d and the electrical connectors 150. In this embodiment, the electrical connectors 150d include the electrically conductive bars 154 connected to the side edges 137 of the circuit board body 131.

A first shell 110d includes the sidewalls 114d, the through slots 116 located on the sidewalls 114d, the plate 113d connected to the sidewalls 114d, and the recessed holes 117 located on the plate 113d. The positions of the recessed holes 117 correspond to the positions of the through slots 116. The electrically conductive bars 154 are located in the through slots 116 and the recessed holes 117 and are spaced apart from the first shell 110d.

When the power module 100h of this embodiment is mounted on the motherboard, the electrically conductive ribs of the motherboard (not shown) may extend into the U-shaped recessed grooves of the electrical connectors 150d to be aligned with and conductive with the power module 100h. Specifically, the electrically conductive rib of the motherboard is in a shape of, for example, a cylinder (but not limited thereto). The outer contour of the electrically conductive rib corresponds to the inner contour of the U-shaped recessed groove of the electrical connectors 150d. Therefore, when the power module 100h is mounted on the motherboard, the electrically conductive ribs of the motherboard are inserted into the U-shaped recessed groove of the electrical connectors 150d. In other words, the electrical connectors 150d contacts/encloses a part of the electrically conductive ribs of the motherboard and are conductive.

In summary of the foregoing, the second shell of the power module according to the embodiments of the disclosure is closed relative to the first shell and forms the accommodating space together with the first shell. The circuit board assembly is disposed in the accommodating space and includes the power components. The heat dissipation encapsulation is filled in the accommodating space and covers the circuit board assembly. In the power module of the disclosure, with the above design, the heat dissipation encapsulation filled in the accommodating space can effectively transfer the high heat generated by the circuit board assembly to the shells to improve the heat dissipation efficiency. Compared with the conventional structure, which needs to lower the temperature using heat dissipation fins that occupy a larger space, the power module of the disclosure has a smaller volume and a more compact component arrangement, thereby achieving high power density.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power module, comprising:
a first shell;
a second shell closed relative to the first shell and forming an accommodating space together with the first shell;
a circuit board assembly disposed in the accommodating space, and comprising:
a circuit board body;
a plurality of power components disposed on the circuit board body; and
a plurality of electrical connectors electrically connected to the circuit board body, wherein the electrical connectors are exposed from the first shell; and
a heat dissipation encapsulation filled in the accommodating space and covering the circuit board assembly.

2. The power module according to claim 1, wherein the circuit board body comprises a first surface and a second surface opposite to each other, a part of the power components is disposed on the first surface of the circuit board body, and another part of the power components is disposed on the second surface of the circuit board body.

3. The power module according to claim 1, wherein the circuit board body is an insulated metal substrate, the circuit board body comprises a heat dissipation layer, an insulating layer, and a circuit layer stacked in sequence, and the power components are disposed on the circuit layer.

4. The power module according to claim 3, wherein the heat dissipation layer is thermally coupled to the second shell.

5. The power module according to claim 3, wherein a thickness of the heat dissipation layer is greater than a thickness of the insulating layer, and the thickness of the heat dissipation layer is greater than a thickness of the circuit layer.

6. The power module according to claim 1, wherein the electrical connectors comprise a plurality of electrically conductive pillars, the circuit board body comprises a first surface, at least a part of the power components is disposed on the first surface, the first shell comprises a plurality of holes, and the electrically conductive pillars protrude from the first surface, pass through the holes, and protrude from the first shell.

7. The power module according to claim 1, wherein the electrical connectors comprise a plurality of electrically conductive bars connected to side edges of the circuit board body, the first shell comprises a plurality of sidewalls and a plurality of through slots located on the sidewalls, and the electrically conductive bars are located in the through slots and spaced apart from the first shell.

8. The power module according to claim 7, wherein each of the electrically conductive bars is in a shape of a U-shaped bar.

9. The power module according to claim 7, wherein the electrically conductive bars are flush with or below a surface of the first shell away from the second shell.

10. The power module according to claim 1, wherein the electrical connectors are located around the power components.

11. The power module according to claim 1, wherein the power components comprise an inductor, a transistor, a coil transformer, or a planar transformer.

12. The power module according to claim 1, wherein a thermal conductivity coefficient of the second shell is greater than or equal to a thermal conductivity coefficient of the first shell, and the heat dissipation encapsulation is thermally coupled to the second shell.

13. The power module according to claim 1, wherein a material of the first shell comprises metal or a ceramic material.

14. The power module according to claim 1, wherein a material of the second shell comprises aluminum or copper.

15. The power module according to claim 1, wherein the first shell is a box, and the second shell is a thermally conductive plate.

16. The power module according to claim 1, wherein the first shell is a plate, and the second shell is a thermally conductive box.

17. The power module according to claim 1, wherein a thermal conductivity coefficient of the second shell is greater than or equal to a thermal conductivity coefficient of the first shell, and a surface area of the second shell is greater than a surface area of the first shell.

18. The power module according to claim 1, wherein the power module does not comprise a heat dissipation fin.

19. The power module according to claim 1, wherein the heat dissipation encapsulation is in direct contact with the first shell and the second shell.

20. The power module according to claim 1, wherein the heat dissipation encapsulation is in direct contact with the power components.
